(19) United States
(12) Patent Application Publication
(10) Pub. No.: US 2012/0098536 A1
(43) Pub. Date: Apr. 26, 2012

(54) RADIO FREQUENCY MAGNETIC RESONANCE IMAGING COIL FOR INCREASED QUANTA GATHERING

(75) Inventors: Robert Allen Liedke, Dacula, GA (US); Jonathan Wayne Folsom, Maple Valley, WA (US)

(73) Assignee: 5SPHERE, LLC, Pittsburgh, PA (US)

(21) Appl. No.: 13/276,455

(22) Filed: Oct. 19, 2011

Related U.S. Application Data
(60) Provisional application No. 61/394,853, filed on Oct. 20, 2010.

(51) Int. Cl. G01R 33/48; G01R 33/44

(52) U.S. Cl. 324/309; 324/322

(57) ABSTRACT

A radio frequency (RF) magnetic resonance imaging (MRI) coil for increased quanta gathering is described. An apparatus may comprise an RF receiver coil comprising multiple coil windings. Each coil winding may comprise a compressed cylindrical tube having a defined thickness to form a surface to collect a first quanta of emitted energy. Adjacent coil windings may be spaced apart a defined distance to form coil gaps to allow a second quanta of emitted energy to pass through the coil gaps. Other embodiments are described and claimed.

### RELATED APPLICATION

This non-provisional application claims priority to U.S. Provisional Patent Application 61/394,853 titled “Radio Frequency Magnetic Resonance Imaging Coil For Increased Quanta Gathering” filed on Oct. 20, 2010, which is hereby incorporated by reference in its entirety.

### BACKGROUND

Magnetic resonance imaging (MRI), nuclear magnetic resonance imaging (NMRI), or magnetic resonance tomography (MRT) is a medical imaging technique used in radiology to visualize detailed internal structures. MRI makes use of the property of nuclear magnetic resonance (NMR) to image nuclei of atoms inside the body.

An MRI system uses a powerful magnetic field to align the magnetization of some atoms in the body, and radio frequency (RF) fields to systematically alter the alignment of this magnetization. This causes the nuclei to produce a rotating magnetic field detectable by the MRI system, and this information is recorded to construct an image of the scanned area of the body. Strong magnetic field gradients cause nuclei at different locations to rotate at different speeds. Three dimensional (3-D) spatial information can be obtained by providing gradients in each direction.

MRI systems provide good contrast between the different soft tissues of the body, which makes it especially useful in imaging the brain, muscles, the heart, and cancers compared with other medical imaging techniques such as computed tomography (CT) or X-rays. Unlike CT scans or traditional X-rays, MRI uses no ionizing radiation. However, performance and image quality of an MRI system are typically related to a strength of a magnetic field produced by the MRI system, as measured in tesla (T). MRI systems producing higher tesla levels are typically more expensive than MRI systems producing lower tesla levels. For example, 1.5 tesla scanners often cost millions of dollars, while 3.0 tesla scanners may cost multiple millions of dollars. Further, such higher tesla systems often require construction of MRI suites with expensive RF shielding, which can significantly increase deployment costs for a MRI system. Therefore, techniques that can increase higher quality images from lower tesla systems may have significant advantages for MRI systems. It is with respect to these and other considerations that the present improvements have been needed.

### BRIEF DESCRIPTION OF THE DRAWINGS

FIG. 1 illustrates a first embodiment of a radio frequency (RF) receiver coil.

FIG. 2 illustrates a second embodiment of a RF receiver coil.

FIG. 3 illustrates an embodiment of receiver system with a RF receiver coil.

FIG. 4 illustrates an embodiment of a MRI system with a RF receiver coil.

FIG. 5 illustrates an embodiment of a logic flow for an MRI system.

FIG. 6 illustrates an embodiment of a computing architecture.

FIG. 7 illustrates an embodiment of a communications architecture.

### DETAILED DESCRIPTION

Embodiments are generally directed to various techniques for enhanced focusing radio frequency (RF) receiving coils to increase an amount of quanta gathering by the coils. The enhanced focusing RF receiving coils can be used, for example, by magnetic resonance imaging (MRI) devices and applications for both humans and animals. However, the embodiments are not limited specifically to MRI devices, MRI applications, or human and animal targets.

Reference is now made to the drawings, wherein like reference numerals are used to refer to like elements throughout. In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives consistent with the claimed subject matter.

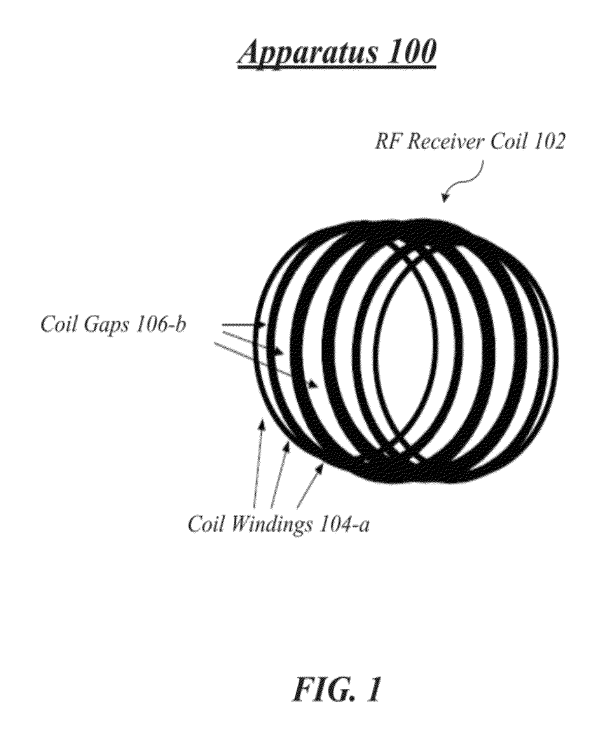

FIG. 1 illustrates an embodiment for an apparatus 100. Although the apparatus 100 shown in FIG. 1 has a limited number of elements in a certain topology, it may be appreciated that the apparatus 100 may include more or less elements in alternate topologies as desired for a given implementation.

In the illustrated embodiment shown in FIG. 1, the apparatus 100 includes an exemplary RF receiver coil 102 suitable for a magnetic resonance image (MRI) device or other devices receiving RF energy. The RF receiver coil 102 may be arranged to receive an electromagnetic field produced by an RF transmitter and a magnet of a MRI device. In general, the RF receiver coil 102 is designed to capture or collect emitted energy, or quanta, from an excited target source. The RF receiver coil 102 is typically formed from materials that have a high level of conductance and permeability (e.g., copper).

Performance for the RF receiver coil 102 may vary according to several design factors. Examples of design factors for a given RF receiver coil 102 may include a spatial relationship to an emitting source (e.g., an RF transmitter), material used for the coil windings, and a number of channels used for collection. In typical implementations, the RF receiver coil 102 is an internal coil array positioned to lie flat with respect to the emitting source. Consequently, quanta emitted from an isocenter of a target have a greater distance to travel to an outer edge of the RF receiver coil 102 than quanta that would be gathered closer to the center. This increase in distance has a detrimental effect on received energy to the RF receiver coil 102 producing a weaker signal.

Embodiments solve these and other problems by providing an enhanced focusing RF receiver coil design that increases a field of view (FOV) within a gantry of a MRI device. The RF receiver coil 102 utilizes the enhanced focusing RF receiver coil design which results in a more efficient gathering of quanta due, in part, to new materials used for coil windings 104-a and by focusing multiple coil windings 104-a within the RF receiver coil 102, among other novel features of the RF receiver coil 102.

The RF receiver coil 102 may comprise multiple coil windings 104-a. Each coil winding 104-a may comprise a compressed cylindrical tube having a defined thickness to form a surface to collect a first quanta of emitted energy. Adjacent coil windings 104-a may be spaced apart a defined distance to form coil gaps 106-b to allow a second quanta of emitted energy to pass through the coil gaps 106-b.

It is worthy to note that “a” and “b” and “c” and similar designators as used herein are intended to be variables representing any positive integer. Thus, for example, if an implementation sets a value for a=5, then a complete set of coil windings 104-a may include coil windings 104-1, 104-2, 104-3, 104-4 and 104-5. The embodiments are not limited in this context.

The coil windings 104-a may comprise a compressed cylindrical tube having a defined thickness to form a surface to collect a first quanta of emitted energy. In various embodiments, the RF receiver coil 102 utilizes coil windings 104-a formed from a suitable coil material formed as tubing rather than a simple wire. In one embodiment, for example, the coil windings 104-a are formed from a cylindrical tube having a 0.25 inches inside diameter (ID). The cylindrical tube is heated and compressed to a defined thickness to provide a compressed cylindrical tube with a surface area providing the desired performance characteristics.

In one embodiment, the uncompressed cylindrical tube may be formed from a material providing a high level of conductance and permeability. In one embodiment, for example, the uncompressed cylindrical tube may be formed from copper. Other materials having characteristics similar to copper may be used as well, such as silver, for example. Any metal or material that has high permeability and a defined molecular lattice work to efficiently conduct the flow of electrons may be used for a given implementation. The embodiments are not limited in this context.

The cylindrical tube is heated and compressed to a defined thickness to provide a compressed cylindrical tube with a surface area providing the desired performance characteristics. In one embodiment, the defined thickness may comprise approximately three millimeters (mm). Other defined thicknesses may be used as well. The embodiments are not limited in this context.

The RF receiver coil 102 may comprise multiple coil windings 104-a. The number of multiple coil windings 104-a may vary depending on a number of design factors, such as a size of a target (e.g., a human or animal patient), a size of a desired field of view (FOV), a size of a MRI system, a size of a component of an MRI system, a size of an electromagnetic field implemented by a MRI system, and other MRI system design factors. The embodiments are not limited in this context.

Each of the multiple coil windings 104-a may be positioned such that a surface area of the coil winding 104-a remains parallel to a target (e.g., a human or animal patient) to be scanned so that it maintains a perpendicular angle to emitted energy, thereby insuring maximum exposure of the surface area of the coil winding 104-a to the emitted energy and a shortest possible distance of travel of the emitted energy or quanta to be captured from an emitter source, such as an RF transmitter coil, for example. In one embodiment, each of the multiple coil windings 104-a may have a circumference of approximately 16 mm, although other dimensions may be used for a given implementation. The embodiments are not limited in this context.

In various embodiments, the RF receiver coil 102 may have different sets of coil windings 104-a each tilted a different number of degrees towards isocenter of the RF receiver coil 102. In one embodiment, for example, a first set of coil windings 104-a may be tilted a first number of degrees towards an isocenter of the RF receiver coil 102, a second set of coil windings 104-a may be tilted a second number of degrees towards the isocenter of the RF receiver coil 102, and a third set of coil windings 104-a substantially perpendicular to the isocenter of the RF receiver coil 102. Each set of first, second and third sets of coil windings 104-a may include pairs of coil windings 104-a starting on outermost edges of the RF receiver coil 102 and moving towards an isocenter of the RF receiver coil 102. In one embodiment, for example, the first number of degrees may comprise five degrees, and the second number of degrees may comprise three degrees.

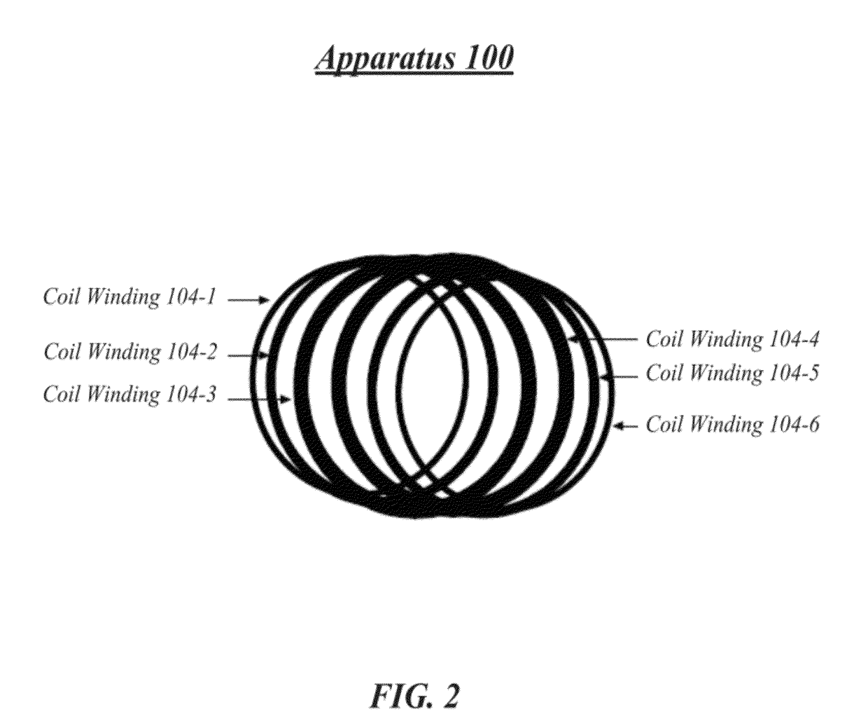

FIG. 2 illustrates another embodiment for an apparatus 100. In the embodiment shown in FIG. 2, the RF receiver coil 102 may have six coil windings 104-1 to 104-6 in sequence. In this configuration, the RF receiver coil 102 may have a first set of coil windings 104-1, 104-6 tilted a first number of degrees towards an isocenter of the RF receiver coil 102, a second set of coil windings 104-2, 104-5 tilted a second number of degrees towards the isocenter of the RF receiver coil 102, and a third set of coil windings 104-3, 104-4 substantially perpendicular to the isocenter of the RF receiver coil. In this embodiment, for example, the first number of degrees may comprise five degrees, and the second number of degrees may comprise three degrees.

Adjacent coil windings 104-a may be spaced apart a defined distance to form coil gaps 106-b to allow a second quanta of emitted energy to pass through the coil gaps 106-b. The defined distance of a coil gap 106-b may comprise a distance selected to reduce mutual inductance to allow an increase in collection of the first quanta of emitted energy. In one embodiment, for example, the defined distance of a coil gap 106-b may comprise approximately 3 mm. The coil gaps 106-b may have a defined distance of 3 mm to reduce any mutual inductance that will allow an increase in quanta capture without the inductance reactance between the coil windings 104-a that would negate these gains. Consequently, quanta will pass through the coil windings 104-a of the RF receiver coil 102 but not before they have had the desired nuclear effect on the coil windings 104-a. It may be appreciated that other defined distances may be used as well to increase or decrease quanta capture for a given implementation. The embodiments are not limited in this context.

The RF receiver coil 102 provides significant advantages over conventional RF coils. Some advantages of this approach allow for a larger RF receiver coil design that will increase a size of a target to be scanned. The focusing of the winding array provides a more “concave” surface and thereby increases the capture of quanta that otherwise would be lost using conventional collection techniques. This increase translates into greater image resolution when compared to a similar surface area coil and/or the ability to produce diagnostic images when scanning larger targets. As one point of comparison with existing RF coil design, for example, the RF receiver coil 102 implementing the proposed dimensions of 16 cm as described herein would have a minimum 50% increase in signal-to-noise over a predicate device using a conventional RF receiver coil.

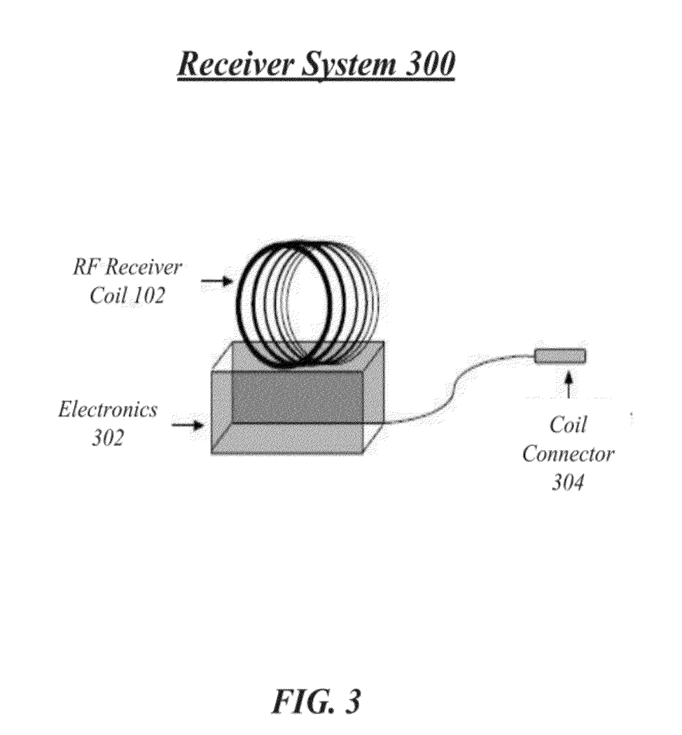

FIG. 3 illustrates an embodiment of a receiver system 300. As shown in FIG. 3, the receiver system 300 includes the RF receiver coil 102, a set of electronics 302, and a coil connector 304. A signal from each coil winding 104-a is received as input by the electronics 302. The electronics 302 may include a pre-amplifier assembly to amplify the received input signals to levels matching an input impedance and signal strength expectations as contained within a given MRI software application. The amplified signal should be presented with a variable DC offset voltage to realize the optimum frequency selection. The electronics 302 may also include tuning and matching circuitry comprising components of a typical high “Q” type to further process or filter the amplified signal. The electronics 302 may output the processed signal via the coil connector 304.

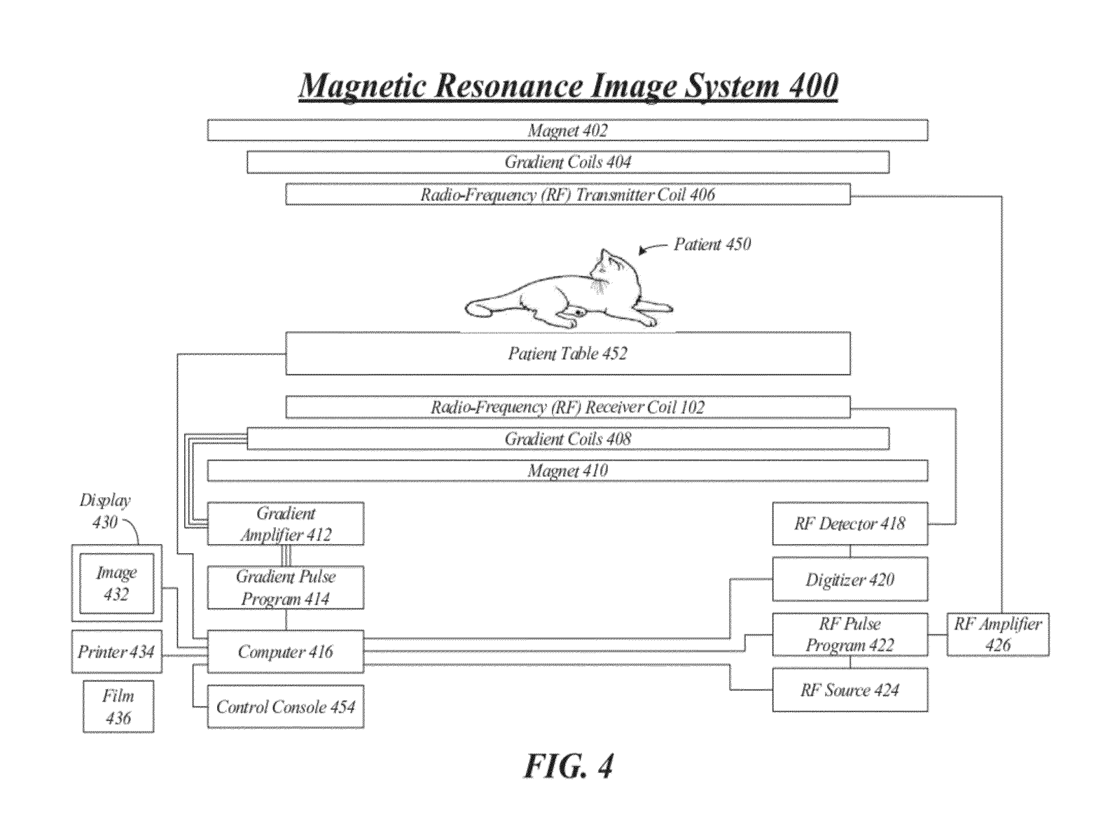

FIG. 4 illustrates an embodiment of a MRI system 400. Although the MRI system 400 shown in FIG. 4 has a limited number of elements in a certain topology, it may be appreciated that the MRI system 400 may include more or less elements in alternate topologies as desired for a given implementation.

In the illustrated embodiment shown in FIG. 4, the MRI system 400 may comprise a set of magnets 402, 410 arranged to produce a magnetic field, and a set of gradient coils 404, 408 arranged to produce a gradient for the magnetic field in the X, Y and Z directions.

The MRI system 400 may further include a set of RF components including a RF transmitter coil 406 and the RF receiver coil 102. The RF transmitter coil 406 may be arranged to produce an electromagnetic field. The RF receiver coil 102 may be arranged to collect quanta from the electromagnetic field generated by the magnets 402, 410, the gradient coils 404, 408, and the RF transmitter coil 406, as described with reference to FIGS. 1, 2.

In general operation, the magnets 402, 410 produce a magnetic field for the imaging procedure. Within the magnets 402-1, 410 are the gradient coils 404, 408 for producing a gradient in the magnetic field in the X, Y, and Z directions. Within the gradient coils is the RF transmitting coil 406. The RF transmitting coil 406 produces an electromagnetic field necessary to rotate the spins by 90°, 180°, or any other value selected for the pulse sequence by the RF pulse program 422. The RF receiver coil 102 also detects the signal from the spins within the body. A human or animal patient 420 is positioned within the magnetic field by a computer controlled patient table 452. The patient table 452 typically has a positioning accuracy of 1 mm. The scan room in which the MRI system 400 is implemented is surrounded by an RF shield. The RF shield prevents the higher power RF pulses from radiating out through the scan room into a surrounding area, such as a hospital, for example. The RF shield also prevents various RF signals from television and radio stations from being detected by the MRI system 400. Some scan rooms are also surrounded by a magnetic shield which contains the magnetic field from extending too far into the hospital. In newer magnets, the magnet shield is an integral part of the magnet.

The MRI system 400 may include a computer 416. The computer 416 may control all components on the MRI system 400. Some RF components under control of the computer 416 are an RF source 424 and a RF pulse program 422. The RF source 424 produces a sine wave of a desired frequency. The RF pulse program 422 shapes RF pulses into apodized sinc pulses. A RF amplifier 426 increases power for the RF pulses from milli-watt range to kilo-watt range. The computer 416 also controls a gradient pulse program 414 which sets the shape and amplitude of each of multiple gradient fields, which in a typical implementation are three gradient fields. A gradient amplifier 412 increases power of the gradient pulses to a level sufficient to drive the gradient coils 404, 408.

In some cases, the MRI system 400 may implement an array processor (not shown) with the computer 416. An array processor is a device which is capable of performing a two-dimensional Fourier transform in fractions of a second. The computer 416 off loads the Fourier transform to this faster device. An operator of the MRI system 400, such as an MRI technician, gives input to the computer 416 through an input device, such as a control console 454.

The computer 416 may receive signals produced by the RF receiver coil 102 as processed by an RF detector 418 and a digitizer 420. The computer may be coupled to an electronic display 430 to present an electronic image 432 of a human or animal target (e.g., patient 450) in the electromagnetic field disposed between the RF transmitter coil 406 and the RF receiver coil 102 using the signal produced by the RF receiver coil 102. A particular imaging sequence of electronic images 432 is selected and customized from the control console 454. The operator can see still or video images 432 of the human or animal patient 450 on an electronic display 430 located on the control console, or can make hard copies of the images as films 436 from a film printer 434.

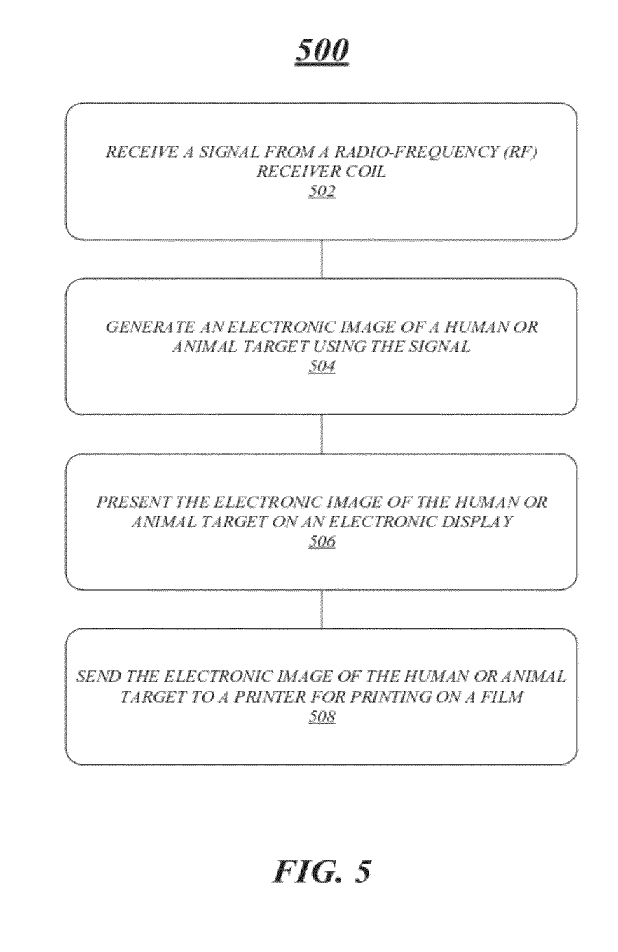

FIG. 5 illustrates one embodiment of a logic flow 500. The logic flow 500 may be representative of some or all of the operations executed by one or more embodiments described herein, such as the MRI system 400, for example.

In the illustrated embodiment shown in FIG. 5, the logic flow 500 may receive by a processor circuit a signal from a RF receiver coil with multiple coil windings, each coil winding having a surface to collect a first quanta of emitted energy, and adjacent coil windings having a coil gap to allow a second quanta of emitted energy to pass through the coil gaps at block 202. For example, a processor circuit implemented by the computer 416 may receive a signal from the RF receiver coil 102 with multiple coil windings 104-a, each coil winding 104-a having a surface to collect a first quanta of emitted energy, and adjacent coil windings 104-a having a coil gap 106-b to allow a second quanta of emitted energy to pass through the coil gaps 106-b. The embodiments are not limited to this example.

The logic flow 500 may generate an electronic image of a human or animal target using the signal at block 504. For example, the processor circuit of the computer 416 may generate an electronic image 432 of a human or animal target 450 using the signal from the RF receiver coil 102 as processed by the RF detector 418 and the digitizer 420. The embodiments are not limited to this example.

The logic flow 500 may present the electronic image of the human or animal target on an electronic display at block 506. For example, the processor circuit of the computer 416 may present the electronic image 432 of the human or animal target 450 on an electronic display 430. The embodiments are not limited to this example.

The logic flow 1000 may send the electronic image of the human or animal target to a printer for printing to a film at block 1008. For example, the processor circuit of the computer 416 may send the electronic image 432 of the human or animal target 450 to a printer 434 for printing to a film 436. The embodiments are not limited to this example.

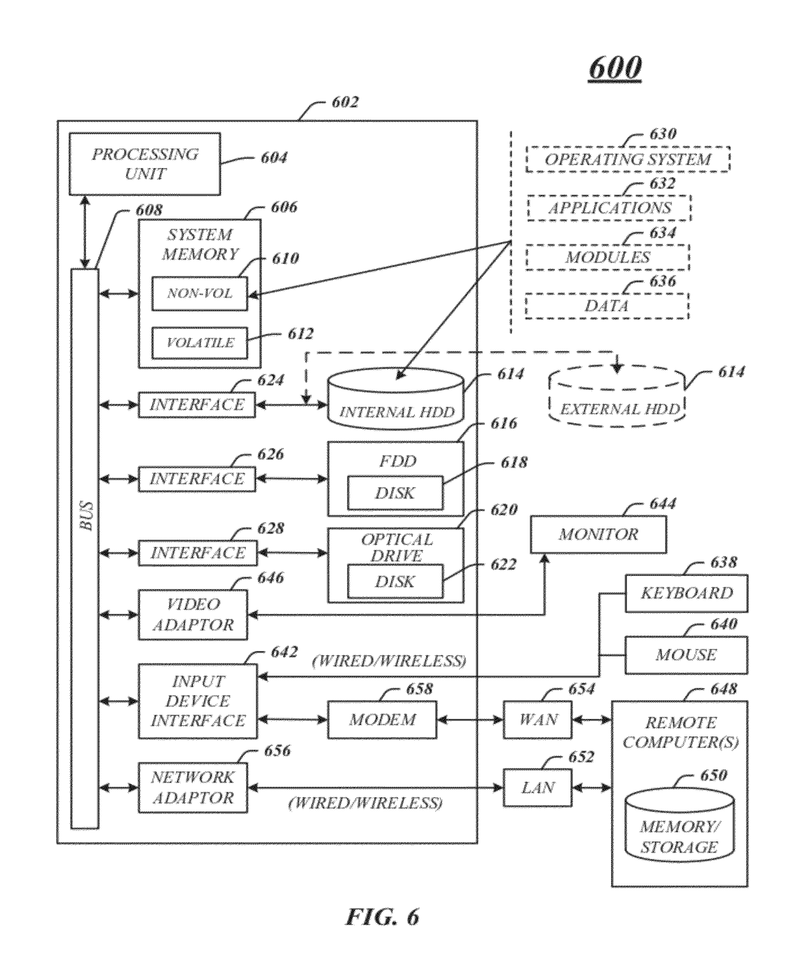

FIG. 6 illustrates an embodiment of an exemplary computing architecture 600 suitable for implementing various embodiments as previously described, such as the computer 416, for example. In one embodiment, the computing architecture 600 may comprise or be implemented as part of an electronic device. Examples of an electronic device may include those described with reference to FIG. 8, among others. The embodiments are not limited in this context.

As used in this application, the terms “system” and “component” are intended to refer to a computer-related entity, either hardware, a combination of hardware and software, software, or software in execution, examples of which are provided by the exemplary computing architecture 600. For example, a component can be, but is not limited to being, a process running on a processor, a processor, a hard disk drive, multiple storage drives (of optical and/or magnetic storage medium), an object, an executable, a thread of execution, a program, and/or a computer. By way of illustration, both an application running on a server and the server can be a component. One or more components can reside within a process and/or thread of execution, and a component can be localized on one computer and/or distributed between two or more computers. Further, components may be communicatively coupled to each other by various types of communications media to coordinate operations. The coordination may involve the uni-directional or bi-directional exchange of information. For instance, the components may communicate information in the form of signals communicated over the communications media. The information can be implemented as signals allocated to various signal lines. In such allocations, each message is a signal. Further embodiments, however, may alternatively employ data messages. Such data messages may be sent across various connections. Exemplary connections include parallel interfaces, serial interfaces, and bus interfaces.

The computing architecture 600 includes various common computing elements, such as one or more processors, multi-core processors, co-processors, memory units, chipsets, controllers, peripherals, interfaces, oscillators, timing devices, video cards, audio cards, multimedia input/output (I/O) components, power supplies, and so forth. The embodiments, however, are not limited to implementation by the computing architecture 600.

As shown in FIG. 6, the computing architecture 600 comprises a processing unit 604, a system memory 606 and a system bus 608. The processing unit 604 can be any of various commercially available processors, including without limitation an AMD® Athlon®, Duron® and Opteron® processors; ARM® application, embedded and secure processors; IBM® and Motorola® DragonBall® and PowerPC® processors; IBM and Sony® Cell processors; Intel® Celeron®, Core (2) Duo®, Itanium®, Pentium®, Xeon®, and XScale® processors; and similar processors. Dual microprocessors, multi-core processors, and other multi-processor architectures may also be employed as the processing unit 604.

The system bus 608 provides an interface for system components including, but not limited to, the system memory 606 to the processing unit 604. The system bus 608 can be any of several types of bus structure that may further interconnect to a memory bus (with or without a memory controller), a peripheral bus, and a local bus using any of a variety of commercially available bus architectures. Interface adapters may connect to the system bus 608 via a slot architecture. Example slot architectures may include without limitation Accelerated Graphics Port (AGP), Card Bus, (Extended) Industry Standard Architecture ((E)ISA), Micro Channel Architecture (MCA), NuBus, Peripheral Component Interconnect (Extended) (PCI(X)), PCI Express, Personal Computer Memory Card International Association (PCMCIA), and the like.

The computing architecture 600 may comprise or implement various articles of manufacture. An article of manufacture may comprise a computer-readable storage medium to store logic. Examples of a computer-readable storage medium may include any tangible media capable of storing electronic data, including volatile memory or non-volatile memory, removable or non-removable memory, erasable or non-erasable memory, writeable or re-writeable memory, and so forth. Examples of logic may include executable computer program instructions implemented using any suitable type of code, such as source code, compiled code, interpreted code, executable code, static code, dynamic code, object-oriented code, visual code, and the like.

The system memory 606 may include various types of computer-readable storage media in the form of one or more higher speed memory units, such as read-only memory (ROM), random-access memory (RAM), dynamic RAM (DRAM), Double-Data-Rate DRAM (DDRAM), synchronous DRAM (SDRAM), static RAM (SRAM), programmable ROM (PROM), erasable programmable ROM (EPROM), electrically erasable programmable ROM (EEPROM), flash memory, polymer memory such as ferroelectric polymer memory, ovonic memory, phase change or ferroelectric memory, silicon-oxide-nitride-oxide-silicon (SONOS) memory, magnetic or optical cards, an array of devices such as Redundant Array of Independent Disks (RAID) drives, solid state memory devices (e.g., USB memory, solid state drives (SSD) and any other type of storage media suitable for storing information. In the illustrated embodiment shown in FIG. 6, the system memory 606 can include non-volatile memory 610 and/or volatile memory 612. A basic input/output system (BIOS) can be stored in the non-volatile memory 610.

The computer 602 may include various types of computer-readable storage media in the form of one or more lower speed memory units, including an internal (or external) hard disk drive (HDD) 614, a magnetic floppy disk drive (FDD) 616 to read from or write to a removable magnetic disk 618, and an optical disk drive 620 to read from or write to a removable optical disk 622 (e.g., a CD-ROM or DVD). The HDD 614, FDD 616 and optical disk drive 620 can be connected to the system bus 608 by a HDD interface 624, an FDD interface 626 and an optical drive interface 628, respectively. The HDD interface 624 for external drive implementations can include at least one or both of Universal Serial Bus (USB) and IEEE 1394 interface technologies.

The drives and associated computer-readable media provide volatile and/or nonvolatile storage of data, data structures, computer-executable instructions, and so forth. For example, a number of program modules can be stored in the drives and memory units 610, 612, including an operating system 630, one or more application programs 632, other program modules 634, and program data 636. In one embodiment, the one or more application programs 632, other program modules 634, and program data 636 can include, for example, the various applications and/or components of the system 100.

A user can enter commands and information into the computer 602 through one or more wire/wireless input devices, for example, a keyboard 638 and a pointing device, such as a mouse 640. Other input devices may include microphones, infra-red (IR) remote controls, radio-frequency (RF) remote controls, game pads, stylus pens, card readers, dongles, finger print readers, gloves, graphics tablets, joysticks, keyboards, retina readers, touch screens (e.g., capacitive, resistive, etc.), trackballs, trackpads, sensors, styluses, and the like. These and other input devices are often connected to the processing unit 604 through an input device interface 642 that is coupled to the system bus 608, but can be connected by other interfaces such as a parallel port, IEEE 1394 serial port, a game port, a USB port, an IR interface, and so forth.

A monitor 644 or other type of display device is also connected to the system bus 608 via an interface, such as a video adaptor 646. The monitor 644 may be internal or external to the computer 602. In addition to the monitor 644, a computer typically includes other peripheral output devices, such as speakers, printers, and so forth.

The computer 602 may operate in a networked environment using logical connections via wire and/or wireless communications to one or more remote computers, such as a remote computer 648. The remote computer 648 can be a workstation, a server computer, a router, a personal computer, portable computer, microprocessor-based entertainment appliance, a peer device or other common network node, and typically includes many or all of the elements described relative to the computer 602, although, for purposes of brevity, only a memory/storage device 650 is illustrated. The logical connections depicted include wire/wireless connectivity to a local area network (LAN) 652 and/or larger networks, for example, a wide area network (WAN) 654. Such LAN and WAN networking environments are commonplace in offices and companies, and facilitate enterprise-wide computer networks, such as intranets, all of which may connect to a global communications network, for example, the Internet.

When used in a LAN networking environment, the computer 602 is connected to the LAN 652 through a wire and/or wireless communication network interface or adaptor 656. The adaptor 656 can facilitate wire and/or wireless communications to the LAN 652, which may also include a wireless access point disposed thereon for communicating with the wireless functionality of the adaptor 656.

When used in a WAN networking environment, the computer 602 can include a modem 658, or is connected to a communications server on the WAN 654, or has other means for establishing communications over the WAN 654, such as by way of the Internet. The modem 658, which can be internal or external and a wire and/or wireless device, connects to the system bus 608 via the input device interface 642. In a networked environment, program modules depicted relative to the computer 602, or portions thereof, can be stored in the remote memory/storage device 650. It will be appreciated that the network connections shown are exemplary and other means of establishing a communications link between the computers can be used.

The computer 602 is operable to communicate with wire and wireless devices or entities using the IEEE 802 family of standards, such as wireless devices operatively disposed in wireless communication (e.g., IEEE 802.11 over-the-air modulation techniques). This includes at least Wi-Fi (or Wireless Fidelity), WiMax, and Bluetooth™ wireless technologies, among others. Thus, the communication can be a predefined structure as with a conventional network or simply an ad hoc communication between at least two devices. Wi-Fi networks use radio technologies called IEEE 802.11x (a, b, g, n, etc.) to provide secure, reliable, fast wireless connectivity. A Wi-Fi network can be used to connect computers to each other, to the Internet, and to wire networks (which use IEEE 802.3-related media and functions).

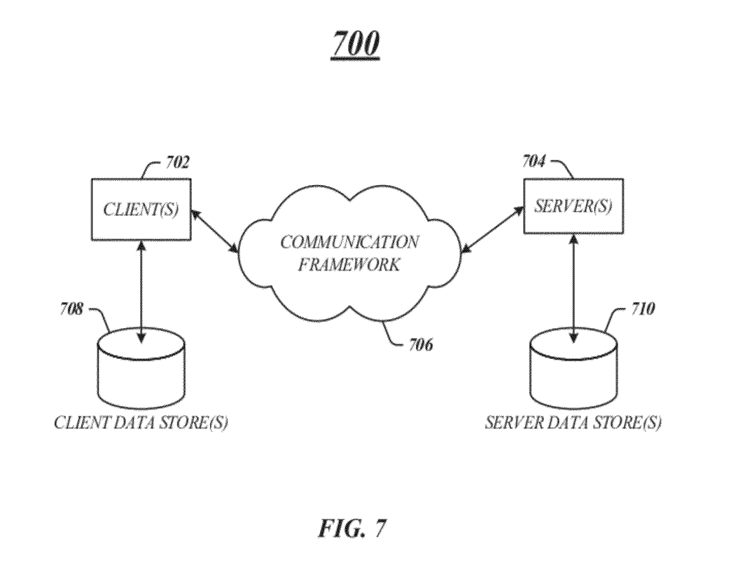

FIG. 7 illustrates a block diagram of an exemplary communications architecture 700 suitable for implementing various embodiments as previously described. For example, the computer 416 may use the communications architecture 700 to send electronic images 432 captured by the MRI system 400 to a remote device using a tele-radiology network. The remote device may comprise, for example, a computer to present the electronic images 432 to a radiologist, and send reports from the radiologist to an attending physician of the patient 450 that ordered the MRI scans. The communications architecture 700 includes various common communications elements, such as a transmitter, receiver, transceiver, radio, network interface, baseband processor, antenna, amplifiers, filters, power supplies, and so forth. The embodiments, however, are not limited to implementation by the communications architecture 700.

As shown in FIG. 7, the communications architecture 700 comprises includes one or more clients 702 and servers 704. The clients 702 may implement the client device 910. The servers 704 may implement the server device 950. The clients 702 and the servers 704 are operatively connected to one or more respective client data stores 708 and server data stores 710 that can be employed to store information local to the respective clients 702 and servers 704, such as cookies and/or associated contextual information.

The clients 702 and the servers 704 may communicate information between each other using a communication framework 706. The communications framework 706 may implement any well-known communications techniques and protocols. The communications framework 706 may be implemented as a packet-switched network (e.g., public networks such as the Internet, private networks such as an enterprise intranet, and so forth), a circuit-switched network (e.g., the public switched telephone network), or a combination of a packet-switched network and a circuit-switched network (with suitable gateways and translators).

The communications framework 706 may implement various network interfaces arranged to accept, communicate, and connect to a communications network. A network interface may be regarded as a specialized form of an input output interface. Network interfaces may employ connection protocols including without limitation direct connect, Ethernet (e.g., thick, thin, twisted pair 10/100/1000 Base T, and the like), token ring, wireless network interfaces, cellular network interfaces, IEEE 802.11a-x network interfaces, IEEE 802.16 network interfaces, IEEE 802.20 network interfaces, and the like. Further, multiple network interfaces may be used to engage with various communications network types. For example, multiple network interfaces may be employed to allow for the communication over broadcast, multicast, and unicast networks. Should processing requirements dictate a greater amount speed and capacity, distributed network controller architectures may similarly be employed to pool, load balance, and otherwise increase the communicative bandwidth required by clients 702 and the servers 704. A communications network may be any one and the combination of wired and/or wireless networks including without limitation a direct interconnection, a secured custom connection, a private network (e.g., an enterprise intranet), a public network (e.g., the Internet), a Personal Area Network (PAN), a Local Area Network (LAN), a Metropolitan Area Network (MAN), an Operating Missions as Nodes on the Internet (OMNI), a Wide Area Network (WAN), a wireless network, a cellular network, and other communications networks.

Some embodiments may be described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Further, some embodiments may be described using the expression “coupled” and “connected” along with their derivatives. These terms are not necessarily intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still co-operate or interact with each other.

It is emphasized that the Abstract of the Disclosure is provided to allow a reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

What has been described above includes examples of the disclosed architecture. It is, of course, not possible to describe every conceivable combination of components and/or methodologies, but one of ordinary skill in the art may recognize that many further combinations and permutations are possible. Accordingly, the novel architecture is intended to embrace all such alterations, modifications and variations that fall within the spirit and scope of the appended claims.

1. An apparatus, comprising:
a radio-frequency (RF) receiver coil with multiple coil windings, each coil winding comprising a compressed cylindrical tube having a defined thickness to form a surface to collect a first quanta of emitted energy, with adjacent coil windings spaced apart a defined distance to form a coil gap to allow a second quanta of emitted energy to pass through the coil gaps.

2. The apparatus of claim 1, the compressed cylindrical tube formed from an uncompressed cylindrical tube having an inside diameter of 0.25 inches.

3. The apparatus of claim 1, the cylindrical tube comprising a permeable material.

4. The apparatus of claim 3, the permeable material comprising copper.

5. The apparatus of claim 1, the defined thickness comprising three millimeters.

6. The apparatus of claim 1, the RF receiver coil having a first set of coil windings tilted a first number of degrees towards an isocenter of the RF receiver coil, a second set of coil windings tilted a second number of degrees towards the isocenter of the RF receiver coil, and a third set of coil windings substantially perpendicular to the isocenter of the RF receiver coil.

7. The apparatus of claim 1, the RF receiver coil having six coil windings in sequence, with a first set of coil windings comprising a first coil winding and a sixth coil winding tilted a first number of degrees towards an isocenter of the RF receiver coil, a second set of coil windings comprising a second coil winding and a fifth coil winding tilted a second number of degrees towards the isocenter of the RF receiver coil, and a third set of coil windings comprising a third coil winding and a fourth coil winding substantially perpendicular to the isocenter of the RF receiver coil.

8. The apparatus of claim 7, the first number of degrees comprising five degrees, and the second number of degrees comprising three degrees.

9. The apparatus of claim 1, the defined distance of a coil gap comprising a distance selected to reduce mutual inductance to allow an increase in collection of the first quanta of emitted energy.

10. The apparatus of claim 1, the defined distance of a coil gap comprising 3 millimeters.

11. A magnetic resonance imaging (MRI) system, comprising:
a magnet operative to produce a magnetic field;
a RF transmitter operative to produce an electromagnetic field; and
a RF receiver coil with multiple coil windings, each coil winding comprising a compressed cylindrical tube having a defined thickness to form a surface to collect a first quanta of the electromagnetic field, with adjacent coil windings spaced apart a defined distance to form a coil gap to allow a second quanta of the electromagnetic field to pass through the coil gaps.

12. The MRI system of claim 11, the defined thickness comprising three millimeters.

13. The MRI system of claim 11, the RF receiver coil having a first set of coil windings tilted a first number of degrees towards an isocenter of the RF receiver coil, a second set of coil windings titled a second number of degrees towards the isocenter of the RF receiver coil, and a third set of coil windings substantially perpendicular to the isocenter of the RF receiver coil.

14. The MRI system of claim 11, the first number of degrees comprising five degrees, and the second number of degrees comprising three degrees.

15. The MRI system of claim 11, the defined distance of a coil gap comprising 3 millimeters.

16. The MRI system of claim 11, comprising:
a computing device to receive a signal produced by the RF receiver coil; and
an electronic display coupled to the computing device to present an electronic image of a human or animal target in the electromagnetic field disposed between the RF transmitter and the RF receiver coil using the signal produced by the RF receiver coil.

17. The MRI system of claim 11, comprising:
a computing device to receive a signal produced by the RF receiver coil; and
an electronic printer coupled to the computing device to print a film with an electronic image of a human or animal target in the electromagnetic field disposed between the RF transmitter and the RF receiver coil using the signal produced by the RF receiver coil.

18. A computer-implemented method, comprising:
receiving by a processor circuit a signal from a radio frequency (RF) receiver coil with multiple coil windings, each coil winding having a surface to collect a first quanta of emitted energy, and adjacent coil windings having a coil gap to allow a second quanta of emitted energy to pass through the coil gap; and
generating an electronic image of a human or animal target using the signal.

19. The computer-implement method of claim 18, comprising presenting the electronic image of the human or animal target on an electronic display.

20. The computer-implemented method of claim 18, comprising sending the electronic image of the human or animal target to a printer for printing to a film.
